(19) United States
(12) Patent Application Publication
(10) Pub. No.: US 2007/0248895 A1
(43) Pub. Date: Oct. 25, 2007

(54) METHOD FOR REDUCTION OF PHOTOMASK DEFECTS

(75) Inventor: Wei-Yu Su, Taipei (TW)

Correspondence Address: DUANE MORRIS LLP;IP DEPARTMENT (TSMC), 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 11/767,906

(22) Filed: Jun. 25, 2007

Related U.S. Application Data
(63) Continuation-in-part of application No. 10/040,042, filed on Nov. 7, 2001.

(51) Int. Cl. G03F 1/00

(52) U.S. Cl. 430/5

(57) ABSTRACT

A method for reducing defect levels in a photomask by employing a cleaning process which does not degrade the photomask after multiple cycles of cleaning. The method is suitable for patterned metal stencil photomasks and phase shift photomasks. The method employs an alkaline aqueous cleaning solution for a particular time in a particular temperature range. The method results in improved photomask yield after multiple cleaning cycles.

### CROSS REFERENCE TO RELATED APPLICATION

This application is a continuation-in-part of U.S. Ser. No. 10/040,042, filed Nov. 7, 2001.

### FIELD OF THE INVENTION

The invention relates to the field of micro electronics fabrication. More particularly, the invention relates to the field of photomasks employed for pattern formation in micro electronics fabrication.

### DESCRIPTION OF THE RELATED ART

Modern micro electronics devices are fabricated employing patterned layers of micro electronics materials formed upon substrates. Micro electronics materials employed include conductor, semiconductor, and dielectric materials, generally formed as layers on various substrates as well as on underlying layers formed on substrates. Complex patterns are required to achieve the designs of the micro electronics devices. As dimensions have decreased in order to increase component packing density and circuit performance, more emphasis has been placed on the accuracy and alignment of the patterns formed within these micro electronics layers.

Pattern formation is almost universally accomplished by photolithographic methods, employing layers of photosensitive materials known as photoresists. These photoresist layers are formed over the micro electronics material layers and exposed to radiation through patterned stencil photomasks to form patterned photoresist mask layers for subsequent fabrication operations such as etching, patterned deposition and the like. In order to keep pace with the continuous desire for decreased device dimensions, considerable improvements have been made in the radiation sources for exposure to forestall the effects of diffraction. Likewise, improvements have been made in step-and-repeat exposure systems for accurate alignment of succeeding masks employed in a micro electronics fabrication. In order to minimize diffraction effects at the edges of patterns, which are becoming significant now that dimensions of the order of a fraction of a micrometer are currently being employed, improved methods of photomask fabrication are being developed.

As diffraction effects become significant, improved mask technology, such as the use of phase contrast or phase shift photomasks, have been developed. These phase shift photomasks consist of differentially etched regions engraved into the substrate of the transparent mask adjacent to the edge of an opaque patterned metal layer, such that there is phase interference of the radiation at the edge to improve contrast and eliminate diffraction blurring of the image edge. The fabrication of photomasks and phase shift photomasks employ methods and materials analogous to those employed in micro electronics device fabrication. Thus, there are many chemical procedures, which require patterned etching and material removal. This places a stringent requirement on cleaning procedures employed in photomask fabrication, to remove defects and particulate residues while avoiding damage to the patterned metal layers and the engraved patterns within the phase shift mask substrate. While in general procedures for photomask cleaning are satisfactory, the removal of defects without introduction of additional defects and degradation of the patterned metal layers is not without problems.

For example, the use of de-ionized water to remove particles and residues, although effective in the sense of not reacting with the photomask constituents themselves, does not always completely remove all defects and residues. Although water is a good solvent for polar substances, it is ineffective against organic substances and has a high surface tension. More reactive acid or alkaline reagents in aqueous solution, such as sodium hydroxide and hydrogen peroxide, are more effective in removing extraneous defects, but tend to attack the metal pattern layers, some more than others, so as to cause more defects to appear in the image and to degrade the dimensions of the metal pattern. Finally, it is not always feasible to re-clean photomasks for more than a few cycles due to eventual degradation of the patterned layers by the reagents employed in the cleaning method.

It is thus toward the goal of reducing the defect levels in photomasks by employment of suitable cleaning procedures that the present invention is generally directed.

Methods and materials have been proposed through which photomasks and phase shift photomasks may be cleaned after fabrication, repair or use to reduce defects and residues. For example, Datta et al, in U.S. Pat. No. 5,152,878, disclose a method for cleaning residual stains from patterned molybdenum masks. The method employs an electrolytic removal of stains from the molybdenum mask, which is the anode in an electrolytic cell with phosphoric acid and glycerol as the electrolyte, and steel plates as cathode. A power supply supplies a constant voltage between 5 and 10 volts.

Further, Pierrat, in U.S. Pat. No. 5,695,896, discloses a method for fabricating a phase shift mask which employs cleaning steps after each dry or wet etching step. The patterned metal layer is formed employing chromium. The cleaning methods employed are not specified.

Finally, Lee et al., in U.S. Pat. No. 6,139,993, discloses a method for cleaning after repair of defects in a patterned metal layer photomask, which may also be a phase shift photomask.

Desirable in the art of micro electronics fabrication are additional methods for reducing the defect levels in photomasks by cleaning methods to improve yields and reduce costs of micro electronics devices.

It is toward these goals that the present invention is generally and more specifically directed.

### SUMMARY OF THE INVENTION

A first object of the present invention is to provide a method for reducing the level of defects in photomasks by employing a cleaning procedure after fabrication or use of the photomask.

A second object of the present invention is to provide a method in accord with the first object of the present invention, where the cleaning procedure does not degrade the patterned metal layers of photomasks and phase shift photomasks.

A third object of the present invention is to provide a method in accord with the first object of the present invention and the second object of the present invention, where the cleaning procedure may be employed for multiple cleaning cycles on a particular photomask without significant degradation.

A fourth object of the present invention is to provide a method in accord with the first object of the present invention, the second object of the present invention and the third object of the present invention, where the method is readily commercially implemented.

In accord with the objects of the present invention, there is provided a method for reducing the defect levels of photomasks by employment of a cleaning procedure without significant degradation of the photomask metal layers. To practice the invention, there is provided a photomask, which is treated with a solution of ammonium hydroxide and hydrogen peroxide in water at a particular concentration and at a particular temperature for a specified time, to remove particulate defects and residues without chemically attacking the patterned metal layers of the photomask. The cleaning procedure may be applied to a particular photomask for multiple cleaning cycles without significant degradation.

The method of the present invention is intended to be employed with beneficial effect for any type of photomask which is formed from patterned metal layers on transparent substrates. The method of the present invention is particularly well suited to the reduction of defects in phase shift photomasks, because these types of photomasks are particularly sensitive to very small amounts of removal of metal, both from the opaque regions of the mask and at the edges of the pattern.

The method of the present invention may be applied to the cleaning of photomasks fabricated employing patterned metal layers formed from opaque materials including but not limited to chromium, molybdenum and molybdenum silicon alloys. The photomasks may be fabricated from transparent substrates including but not limited to fused quartz, high silica content glasses and various optical quality glasses.

The method of the present invention employs materials and methods that are well known in the art of photolithography and micro electronics fabrication, but employs them in a novel and original sequence. Hence the method of the present invention is readily implemented.

### BRIEF DESCRIPTION OF THE DRAWINGS

The objects, features and advantages of the present invention are understood within the context of the Description of the Preferred Embodiments, as set forth below. The Description of the Preferred Embodiments is understood within the context of the accompanying drawings, which form a material part of this disclosure, wherein:

FIG. 1, FIG. 2 and FIG. 3 show a series of schematic cross-sectional drawings illustrating the method of the present invention applied to a phase shift photomask. FIG. 4 and FIG. 5 are graphs which present data illustrative of the method of the present invention. Comparisons are made of variations of the method of the present invention and to the prior art.

### DESCRIPTION OF THE PREFERRED EMBODIMENTS

The present invention provides a method for reducing defect levels in a photomask by employing a cleaning procedure after fabrication or use which does not degrade the patterned metal layer of the photomask. The method may be exercised for multiple cycles on a particular photomask without degradation of the photomask

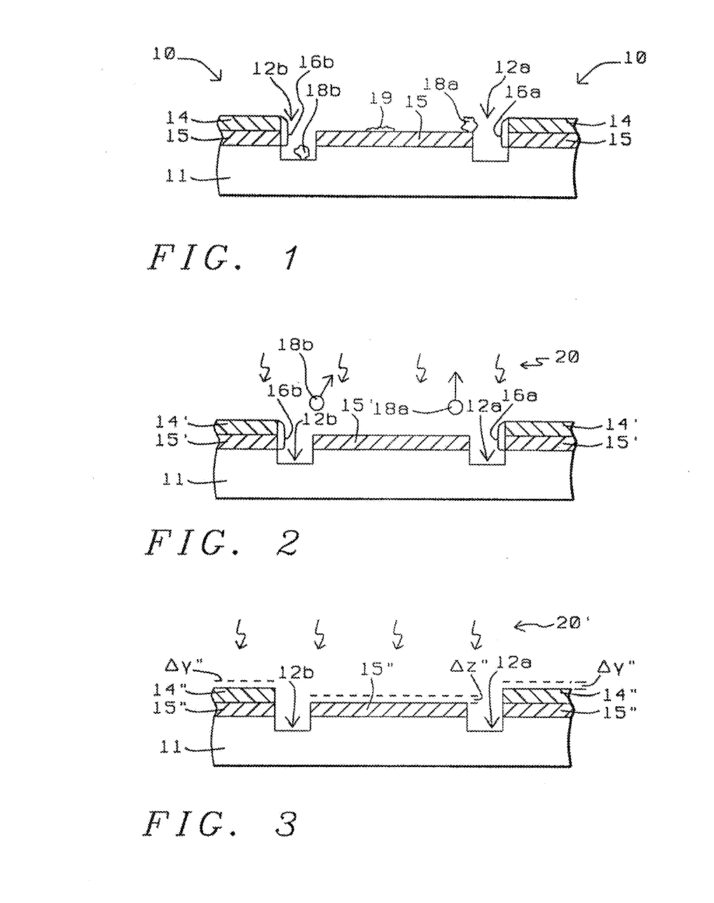

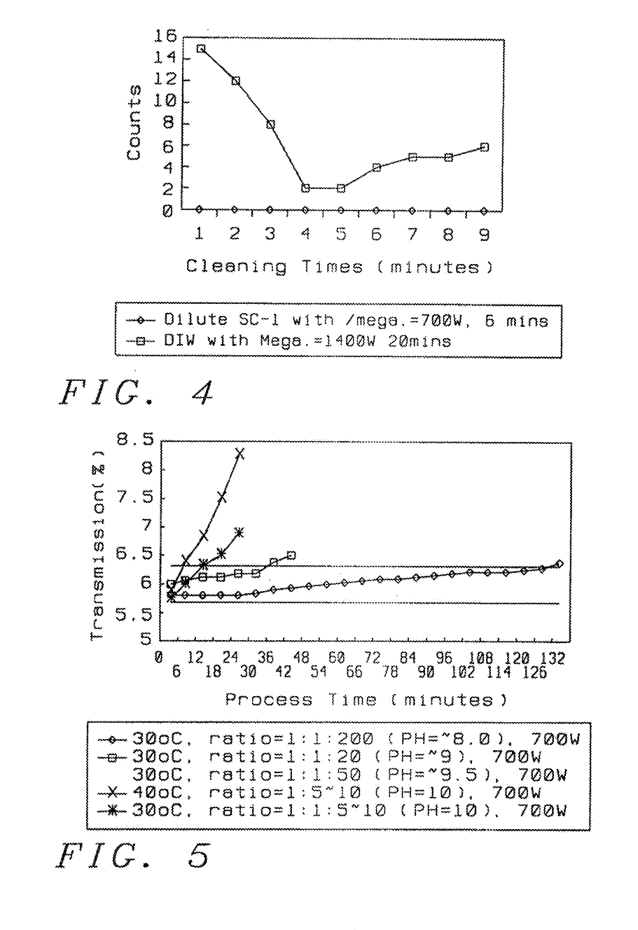

Referring now to FIGS. 1-3, there is shown a series of schematic cross-sectional drawings illustrating the method of the present invention. Shown in FIG. 1 is a schematic cross-sectional drawing illustrating a phase shift photomask after fabrication prior to cleaning. The phase shift photomask 10 consists of a transparent substrate 11 in which an engraved pattern 12a and 12b has been formed by etching. Patterned metal layers 14 and 15 have been formed by etching to produce pattern edges 16a and 16b where there is an optical thickness difference dy sufficient to produce a phase shift for incident radiation of 180° at the edges 16a and 16b. Particles 18a and 18b and residue 19 are left over from the fabrication process.

With respect to the substrate 11 shown in FIG. 1, the substrate 11 may be formed from transparent material which has a high transmission coefficient for the incident radiation to be employed when the photomask is used in exposing photosensitive materials. Preferably, the substrate 11 is formed of fused quartz in which the engraved patterns 12a and 12b are formed employing dry chemical etching methods as are well known in the art of micro electronics fabrication.

With respect to the opaque patterned metal layers 14 and 15 shown in FIG. 1, the opaque patterned metal layers 14 and 15 are formed of materials including but not limited to chromium, molybdenum and molybdenum silicon alloys. Preferably the patterned metal layer 14 is formed from chromium, and the patterned metal layer 15 is formed from molybdenum silicon alloy, deposited by methods as are commonly employed within the art of micro electronics fabrication and patterned by methods and materials as are well known in the art of photolithography.

With respect to the particles 18a and 18b and residue 19 shown in FIG. 1, the particles 18a and 18b and residue 19 are typical of the residual debris left behind by the processes employed to etch and remove materials during photomask fabrication. Typically, particles 18a and 18b are attached to the underlying surfaces by forces of residual chemical attraction or are embedded within the surface, and residues 19 are physically or weakly chemically bound to the underlying surfaces.

Referring now more particularly to FIG. 2, there is shown a schematic cross-sectional diagram illustrating the results of processing the phase shift photomask whose schematic cross-sectional diagram is shown in FIG. 1. Shown in FIG. 2 is a phase shift photomask 10′ equivalent to the phase shift photomask 10 shown in FIG. 1, but where there has been treated the photomask 10′ to a cleaning procedure 20. The result has been the removal of the particles 18a and 18b and the residue 19 along with a minimal removal of the surface of the patterned metal layers 14′ and 15′.

With respect to the cleaning procedure 20 shown in FIG. 2, the cleaning procedure 20 employs a chemical solution of ammonium hydroxide (NH₄OH) and hydrogen peroxide (H₂O₂) in water (H₂O). Preferably the ratio of ammonium hydroxide: hydrogen peroxide: water ranges from 1:1:200 to 1:1:20 respectively. The pH of the cleaning solution is maintained at a value greater than about 7 and less than about 9. The temperature of the cleaning solution is maintained from about 15 degrees centigrade to about 60 degrees centigrade. The treatment time may vary from about 2 to about 20 minutes as needed to remove all the particles and residue. Ultrasonic energy and agitation were supplied to the cleaning solution during the cleaning cycle using methods as are conventionally employed in the art.

With respect to the removal of the particles 18a and 18b and the residue 19, the particles 18a-b and residue 19 are more effectively removed by the cleaning process of the present invention than by the previous cleaning process, which employed de-ionized water. While not wishing to be bound by any particular mechanism, it is hypothesized that particles are more readily removed by the method of the present invention due to the combined efficacy of the cleaning solution to solvate the particles and residue with a double layer due to the lowered Zeta potential of the cleaning solution established by the concentration and the pH of the solution. Additionally, the removal of the particles 18a-b and the residue is assisted by a very slight etching of the metal underneath them. The cleaning process is effective for removing essentially all particles above 0.2 micron in size. The total amount of metal removed by the cleaning process is much less than the amount which would increase the optical transmittance by 6.3%, the latter amount being the requirement to maintain the integrity of the phase shift process at the image edges 16a and 16b.

Referring now more particularly to FIG. 3, there is shown a schematic cross-sectional drawing of a phase shift photomask illustrating the results of further exercise of the method of the present invention. Shown in FIG. 3 is a phase shift photomask otherwise equivalent to the phase shift photomask shown in FIG. 2, but where there has been exercised the cleaning method 20′ of the present invention for a further nine cycles for a total often cleaning cycles. The amount of material removed is dy″ from the chromium layer 14″ and dz″ from the molybdenum silicon layer 15″.

With respect to the cleaning process 20′ shown in FIG. 3, the cleaning process 20′ is equivalent to the cleaning process 20 shown in FIG. 2. With respect to the amounts dy″ and dz″ of chromium and molybdenum removed respectively, the amounts dy″ and dz″ are such that the optical transmittance of the chromium and molybdenum layers after the ten cleaning cycles is equal to or less than 6.3% increase over the original uncleaned value. Therefore, the cleaning process may be exercised repeatedly on the particular photomask, without significant degradation beyond the specified amount of metal removal for at least ten cleaning cycles.

The method of the present invention has been employed to reduce the defect level of photomask with patterned metal layers by treating the photomask with a cleaning solution of ammonium hydroxide, hydrogen peroxide and water to remove particles above 0.2 microns in size. The cleaning process may be exercised for a multiple number of cleaning cycles, up to 10 times without significant removal of metal layers to exceed an increase in optical transmission of 6.3%.

### EXPERIMENTAL RESULTS

The results of experimental measurements performed after employing the method of the present invention and variations thereof are shown in FIG. 3 and FIG. 4, which are graphs displaying the experimental data taken. The measurements of particle density were performed employing Starlight KLA 1301 light scattering apparatus. The comparison shown in FIG. 3 is between the method of the present invention and a cleaning process employing de-ionized water alone. It is clear from the data in FIG. 3 that the method of the present invention removes particles from a photomask much more efficaciously than de-ionized water alone.

In FIG. 4, there is shown the change in optical transmission or decrease in opaqueness of photomask samples treated to various permutations of the method of the present invention. Measurements of optical transmission were performed employing the MPM system supplied by Laser Tech, Inc. The data show that if the concentration of ammonium hydroxide and hydrogen peroxide exceeds a certain limit, the removal rate of metal increases. Even more, if the temperature exceeds a certain limit, the rate of removal of metal increases rapidly. The data shown in FIG. 4 afford the basis for the improved cleaning without degradation obtained by employing the method of the present invention.

The average yield of the phase shift photomask cleaning process employing de-ionized water for an entire year was less than 20%. After incorporating the method of the present invention, the average yield of the cleaning process sector was increased to 80%. The increase in yield was in large part due to the great decrease in particulate matter retained on the photomask after cleaning, in agreement with the data presented in FIG. 4.

As is understood by a person skilled in the art, the preferred embodiments of the present invention are illustrative of the present invention rather than limiting of the present invention. Revisions and modifications may be made to methods, materials and dimensions through which are implemented the preferred embodiment of the present invention without altering the spirit and scope of the present invention as described by the appended claims.

What is claimed is:

1. A method for reducing the amount of particles and residues in photomasks comprising:
providing a photomask having at least one patterned metal layer;
treating the photomask with a cleaning process comprising:
contacting the photomask with a solution comprising ammonium hydroxide, hydrogen peroxide and water maintained at a constant temperature;
agitating the solution by using ultrasonic;
exposing the photomask to the solution;
removing particles and residue; and
exercising the cleaning process on a particular photomask for a multiple number of cleaning cycles without degradation of the photomask, wherein the number of multiple cleaning cycles exercised on a particular photomask without degradation is greater than ten cleaning cycles, and the solution has a pH greater than 7 and less than 9.

2. The method of claim 1, wherein the ratio of ammonium hydroxide:hydrogen peroxide:water of the cleaning solution is from about 1:1:200 to about 1:1:20 respectively by volume.

3. The method of claim 1, wherein a minimal amount of metal layer or layers removed during cleaning results in less than a 6.3% increase in optical transmission.

4. The method of claim 1, wherein the constant temperature range of the solution is from about 15 degrees centigrade to about 60 degrees centigrade.

5. A method for attenuating yield loss in fabrication of micro electronics fabrications employing phase shift photomasks by reducing the amount of particles and residues in said photomasks comprising:
providing a phase shift photomask having patterned metal layers;
treating the phase shift photomask with a cleaning process comprising:
contacting the photomask with a solution comprising ammonium hydroxide, hydrogen peroxide and water maintained at a constant temperature;
agitating the solution by using ultrasonic;
exposing the photomask to the solution;
removing particles and residue greater than about 0.2 microns while removing a minimal amount of patterned metal layers, wherein the removing of particles and residue is assisted by etching of the metal underneath said particles and residue; and
exercising the cleaning process on a particular phase shift photomask for a multiple number of cleaning cycles without degradation of the phase shift photomask, wherein the number of multiple cleaning cycles exercised on a particular photomask without degradation is greater than ten cleaning cycles, and the solution has a pH greater than 7 and less than 9.

6. The method of claim 5, wherein the phase shift mask is formed of patterned layers of chromium and molybdenum silicon alloy.

7. The method of claim 5, wherein the ratio of ammonium hydroxide:hydrogen peroxide:water in the solution ranges from about 1:1:200 to about 1:1:20 respectively by volume.

8. The method of claim 5, whereby the minimal amount of metal layers removed by the cleaning process is equivalent to less than a 6.3% increase in optical transmittance.

9. The method of claim 5, wherein the constant temperature range of the solution is from about 15 degrees centigrade to about 60 degrees centigrade.

10. The method of claim 1, wherein the photomask includes a transparent substrate.

11. The method of claim 1, wherein the photomask includes a fused quartz substrate.

12. The method of claim 5, wherein the photomask includes a transparent substrate.

13. The method of claim 5, wherein the photomask includes a fused quartz substrate.

14. A method for reducing the amount of particles and residues in photomasks comprising:
providing a photomask having patterned metal layers;
treating the photomask with a cleaning process comprising:
contacting the photomask with a solution comprising ammonium hydroxide, hydrogen peroxide and water maintained at a constant temperature;
agitating the solution by using ultrasonic;
exposing the photomask to the solution;
removing particles and residue greater than about 0.2 microns while removing a minimal amount of patterned metal layers, wherein the removing of particles and residue is assisted by etching of the metal underneath said particles and residue; and
exercising the cleaning process on a particular photomask for a multiple number of cleaning cycles without degradation of the photomask, wherein the solution has a pH greater than 7 and less than 9.

15. The method of claim 14, wherein the minimal amount of metal layer or layers removed during cleaning results in less than a 6.3% increase in optical transmission.

16. The method of claim 14, wherein the constant temperature range of the solution is from about 15 degrees centigrade to about 60 degrees centigrade.

17. The method of claim 14, wherein the photomask includes a transparent substrate.

18. The method of claim 14, wherein the photomask includes a fused quartz substrate.
